(19) United States
(12) Patent Application Publication
(10) Pub. No.: US 2023/0005695 A1
(43) Pub. Date: Jan. 5, 2023

(54) ELECTRON SOURCE BASED ON FIELD EMISSION AND PRODUCTION PROCESS FOR SAME

(71) Applicants: CENTRE NATIONAL DE LA RECHERCHE SCIENTIFIQUE, Paris (FR); UNIVERSITÉ D'AIX-MARSEILLE, Marseille Cedex 07 (FR)

(72) Inventors: Alain DEGIOVANNI, Marseille (FR); Evelyne SALANCON, Marseille (FR); Marseille LAPENA, Marseille (FR); Roger MORIN, Marseille (FR)

(21) Appl. No.: 17/756,248

(22) PCT Filed: Nov. 16, 2020
(86) PCT No.: PCT/FR2020/052087

§ 371 Date: May 19, 2022

(30) Foreign Application Priority Data
Nov. 19, 2019 (FR) FR1912909

(51) Int. Cl. H01J 9/02; H01J 37/073

(52) U.S. Cl. CPC H01J 9/025; H01J 37/073; H01J 2237/06341; H01J 2209/012; H01J 37/28

(57) ABSTRACT

The invention relates to an electron source comprising a conductive substrate, a conductor disposed facing the substrate, the electron source emitting an electron beam when the conductor is positively biased with respect to the substrate, and an electrically insulating crystal arranged on the substrate, facing the conductor, the substrate defining with the crystal a void including at least one peak located at a distance from the crystal, the crystal having, in a plane parallel to the substrate, dimensions of less than 100 nm and a thickness of less than 50 nm.

### CROSS-REFERENCE TO RELATED APPLICATIONS

This application is a 371 National Stage of International Application No. PCT/FR2020/052087, filed Nov. 16, 2020, which claims priority to French Patent Application No. FR1912909, filed Nov. 19, 2019, the disclosures of which are herein incorporated by reference in their entirety.

### BACKGROUND

The present invention relates to a field emission electron source. Electron sources are typically used in scanning electron microscopes, as well as in cold cathode flat panel displays and vacuum microelectronics applications.

The electron sources currently used in electron microscopes or flat screens are based on field emission, or thermionic emission.

A material (usually a metal or semiconductor) can only spontaneously emit electrons if it receives and absorbs energy greater than the work output of the material. The energy can be supplied by many means, such as heat, an electric field, or light irradiation. There are thus several types of electron emissions, depending on the energy source used.

In thermionic emission, the energy is provided by the incidence of radiation, especially light, or by heating the substrate. Thermionic emission produces intense beams in a low vacuum (greater than 10⁻² Pa), the equivalent source being relatively large (greater than 10 μm). The brightness of such a source is relatively low (10⁹ A/m²·sr), knowing that it conditions the resolution accessible with this type of source in a microscope.

In field emission (or cold emission), the material is subjected to an electric field of about 1 V/nm. Under the effect of such a field, electrons tunnel through a potential barrier from the Fermi level, at room temperature. In thermionic emission, the heating of the material lowers the Fermi level to the vacuum level, which releases electrons. The field emission with a metal tip produces a beam with a low energy dispersion (ΔE=0.3 eV). A source based on this principle can reach a size below 10 nm. The brightness of such a source can reach values of the order of 10¹³ A/m²·sr. However, the field emission requires a high vacuum (less than 10⁻⁶ Pa) for a lifetime of more than 1000 hours. At higher pressures, the state of the tip rapidly deteriorates and no longer emits.

Schottky emission relies on field effect and thermionic emission, by applying an electric field to a tip, combined with heating of the substrate. Schottky emission produces intense beams in a low vacuum of about 10⁻⁴ Pa, the equivalent size of the source being about 15 nm. The brightness of such a beam is therefore also relatively low, of the order of 5.10¹⁰ A/m²·sr.

The shape of the field-emitting material affects the emission characteristics. Indeed, field emission is most easily obtained from needles or very sharp tips, the end of which has been polished to a substantially hemispherical shape whose radius can be less than 100 nm. When polarization is applied, the electric field lines diverge radially from the tip and the trajectories of the emitted electrons initially follow these field lines.

When the flow of electrons emitted is sufficiently intense, the object subjected to the flow of electrons can emit photons. This phenomenon called “cathodo-luminescence” is used in some flat screens.

The publication “A low-energy electron point-source projection microscope not using a sharp metal tip performs well in long-range imaging”, E. Salancon, A. Degiovanni, L. Lapena, M. Lagaize, R. Morin, Ultramicroscopy Vol. 200 (2019), pp 125-131, describes an electron source formed at the end of a carbon wire of 10 μm diameter and a 0.5×1 μm celadonite crystal of 50 nm thickness, deposited at the end of the wire in a drop of deionized water using a micropipette. This electron source requires an electric field of a few V/μm and can work at pressures higher than 1 Pa, the emissive zone being protected by the crystal. However, this source presents important instabilities and sometimes exhibits multiple emission points, which makes it difficult to use in conventional scanning electron microscopy.

### SUMMARY

Thus, it is desirable to provide an electron source that is sufficiently stable and bright, in particular for providing high resolution when used in a scanning electron microscope, without requiring a large energy input. It is also desirable that this source be robust and have a long lifespan, while being usable at relatively high pressures, compared to the sources of the prior art which generally require a high vacuum.

Embodiments relate to a method of manufacturing an electron source, comprising the steps of: forming a conductive substrate; arranging a conductor facing the substrate; and arranging an electrically insulating crystal on the substrate facing the conductor, the substrate delimiting with the crystal a void including at least one peak located at a distance from the crystal, the crystal having, in a plane parallel to the substrate, dimensions of less than 100 nm, and in a direction perpendicular to the plane, a thickness of less than 50 nm.

According to an embodiment, the method comprises a step of depositing the crystal on the substrate, the substrate having a natural roughness forming the void between the substrate and the crystal.

According to an embodiment, the deposition of the crystal on the substrate is performed by depositing on the substrate a drop containing crystals suspended in deionized water, the drop being produced at an outlet port at a tapered end of a nanopipette by exerting pressure on an inlet port of the nanopipette.

According to an embodiment, the method comprises the steps of: partially filling the nanopipette with deionized water; locally heating the nanopipette to vaporize the water, wherein the water in vapor form is condensed near the tapered end of the micropipette; and filling the nanopipette with deionized water containing suspended crystals.

According to an embodiment, the methods comprises the steps of machining the end of a conductive wire to form a tip and, at an apex of the tip, forming a plateau forming the conductive substrate.

According to an embodiment, the extent of the plateau and the inclination of the tip are adjusted according to a desired divergence of an electron beam produced by the electron source.

According to an embodiment, the method comprises the steps of: forming a nanotip in the substrate; depositing an insulating layer on the substrate; forming a well in the insulating layer to expose the nanotip; filling the well with a sacrificial layer; depositing a single crystal layer on the insulating layer and the sacrificial layer; etching the single crystal layer to form a monocrystalline plate having an edge plumb with an apex of the nanotip; and removing the sacrificial layer to form the void between the substrate and the monocrystalline plate.

Embodiments may also relate to an electron source comprising: a conductive substrate; a conductor arranged facing the substrate, the electron source emitting an electron beam when the conductor is positively biased with respect to the substrate; and an electrically insulating crystal arranged on the substrate, facing the conductor, the substrate delimiting with the crystal a void including at least one peak located at a distance from the crystal, the crystal having, in a plane parallel to the substrate, dimensions of less than 100 nm and a thickness of less than 50 nm.

According to an embodiment, the crystal is placed on the substrate, the substrate having a natural roughness forming the void between the crystal and the substrate, the crystal being supported by peaks on the surface of the substrate.

According to an embodiment, the substrate is formed by a plateau at the apex of a tip at one end of a wire.

According to an embodiment, the plateau has a width between 5 and 50 μm.

According to an embodiment, the substrate has a nanotip located at a distance from the substrate in the void beneath the crystal or in the vicinity of an edge of the crystal, the void being formed by a well formed around and above the nanotip in an electrically insulating layer supporting the crystal.

According to an embodiment, the substrate is tungsten or carbon, and the crystal is diamond or talcum.

According to an embodiment, the crystal has a width of 50 nm and a thickness of 10 nm, these dimensions being defined to within ±10%.

### BRIEF DESCRIPTION OF THE DRAWINGS

Non-limiting examples of embodiments of the invention will be described in the following, in relation to the attached figures among which:

FIG. 1 is a schematic view of an electron source, according to an embodiment,

FIG. 2 is an enlarged schematic view of the electron source,

FIG. 3 schematically shows an electron microscope head integrating the electron source of FIG. 1,

FIG. 4 shows a schematic cross-section of a substrate with multiple electron sources, according to another embodiment.

### DETAILED DESCRIPTION

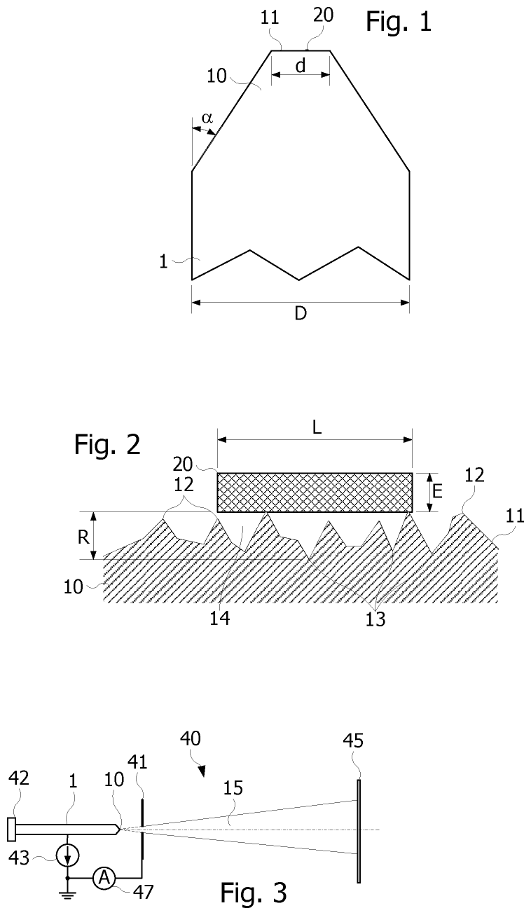

FIGS. 1 and 2 show an electron source according to an embodiment.

This electron source may be used in particular in a scanning microscope. The electron source comprises a conductive wire 1, one end of which is cut into a spike 10, and the spike tip is machined to form a plateau 11. A crystal 20 made of an insulating material is placed on the plateau 11.

The conductive wire 1 may have a diameter D of 100 μm or more and a length of a few mm. The plateau 11 may have a diameter d between 5 and 50 μm, for example around 100 μm. The crystal 20 may have a width (or length) L less than 100 nm, preferably between 10 and 100 nm, for example 50 nm (within ±10%), and a thickness E less than 50 nm, preferably between 1 and 50 nm, for example 10 nm (within ±10%).

In FIG. 2, the plateau 11 has a natural roughness, comparable to the thickness E of the crystal 20, for example equal to the thickness E to within ±50%. Here, the roughness of the surface of a material corresponds to the maximum height of the valleys and peaks appearing on this surface, defined in absolute value compared to the average height of this surface, on the scale of the crystal dimensions.

Thus, the shape and dimensions of these peaks being random, some of the peaks of the plateau 11, in the space delimited between the plateau 11 and the crystal 20, are at a distance less than the thickness of the crystal 20 without this distance being zero, the faces of the crystal being substantially planar (the roughness of the crystal can be less than 0.5 nm). The simple deposition of the crystal 20 on the plateau 11, combined with the roughness of the latter, forms a conductor/vacuum/insulator assembly, in which the vacuum is formed by the spaces 14 between the peaks of the plateau 11 and the crystal 20. Given the very small dimensions of the crystal 20, it is held firmly on the plateau 11 by van der Walls forces.

The angle α formed between the direction of the wire and a generatrix of the conical tip 10 may be adjusted according to the desired divergence of the electron beam generated at the tip 10, knowing that the smaller the angle, the more the produced electron beam diverges. The diameter d of the plateau also has an influence on the divergence of the produced electron beam, knowing that the larger the diameter d of the plateau 11, the less the angle α of the conical part influences the divergence of the beam.

According to various embodiments, the wire 1 is made of a conductive material such as carbon or tungsten. Tungsten has the advantage of being easy to machine. The crystal 20 may be diamond or talcum. The electron source described above has a relatively long lifetime, even when used under relatively high pressures, of the order of 10⁻⁴ Pa or higher.

According to an embodiment, the tip 10 at the end of the wire, may be manufactured for example by electrochemical etching. The plateau 11 may be made by erosion. The crystal 20 may be deposited on the plateau 11 either by means of a nanomanipulator (e.g., piezoelectric) or by means of a micropipette containing deionized water in which several crystals are suspended. The micropipette produces a microdrop of this mixture at its outlet port. The drop is then captured by capillary action, by simple contact of the drop with the tip 10. The drop on the tip 10 dries quickly and deposits the crystal present in the drop. The crystals may be disaggregated in the water by means of ultrasound. The concentration of crystals in the water is adjusted so that the number of crystals per drop is close to one, considering the volume of a drop. The outlet port of the micropipette may be less than 10 μm in diameter to produce drops of substantially this size by applying a pressure of less than 10 kPa, for example 1.5 kPa, to the inlet port of the micropipette. The micropipette may be conventionally manufactured by stretching a capillary tube using a stretcher such as the P2000 stretcher sold by the company SUTTER INSTRUMENT®.

According to an embodiment, a nanopipette is used, with an outlet port smaller than 500 nm, and partially filled with deionized water, for example using the method described in patent application WO 2013/079874, so that the water reaches the tapered portion in the vicinity of the outlet port of the nanopipette. The mixture of deionized water and crystals is then introduced through the inlet port of the nanopipette, and naturally mixes by diffusion with the water already present in the nanopipette through to the outlet port. A drop may be deposited on a support using the nanopipette, and then captured by capillarity by the tip 10 by bringing it into contact with the drop. The dimensions of the drop deposited on the support depend on the speed of movement of the nanopipette along the support as the drop is ejected and on the pressure exerted at the inlet of the nanopipette. The water in the drop on the plateau 11 evaporates very quickly and only one crystal 20 remains.

FIG. 3 shows an electron microscope head 40 incorporating the electron source placed facing a screen, according to an embodiment. The electron microscope may be, for example, of the scanning, projection, or transmission type. The wire 1 is attached to a piezoelectric actuator 42, with the tip 10 facing a diaphragm 41. The wire 1 and the diaphragm 41 are connected to a voltage source 43, to positively bias the diaphragm 41, which thus serves as an anode or extractor with respect to the wire 1 serving as a cathode. The microscope assembly may be placed in a vacuum chamber (not shown) in which the pressure is lowered sufficiently, for example to a value between 10⁻³ and 10⁻⁵ Pa. The actuator 42 is arranged to adjust the distance between the crystal 20 and the diaphragm 41.

An ammeter 47 may be placed between the diaphragm 41 and ground to detect the presence of the electron beam 15 and measure the intensity of the electron beam. As the voltage supplied by the voltage source 43 is gradually increased, an electron beam is observed to appear, with a non-zero current detected by the ammeter 47, starting at about 400 V, with the diaphragm 41 at a distance between 0.5 and 1.5 mm from the crystal 20 or the plateau 11. If the voltage supplied by the voltage source 43 is gradually lowered, the measured current stabilizes at a few hundred nA. In an exemplary implementation, the diaphragm 41 has a diameter of 1 mm.

Thus, the conductor/vacuum/insulator structure provides, thanks to an electric field of the order of a few V/μm, an electron source with an intensity of the order of a hundred nA. It can be observed that this electron source is very stable and follows a Fowler-Nordheim law in a current intensity band of ten orders of magnitude. It can also be observed that a saturation state is reached at about 10 μA for a voltage applied between source 1 and diaphragm 41 of 500 V. Knowing that this phenomenon is generally observed with an electric field of the order of 1 V/nm, it can be assumed that an exaltation of the electric field occurs in the volume at the interface between the conducting plateau 11 and the insulating crystal 20.

It can be observed that at a bias voltage of 500 V, the tip 10 associated with the crystal 20 produces a beam with a low energy dispersion AE between 0.2 and 0.4 eV, an equivalent source size of between 0.5 and 1.5 nm, and a high stability. The brightness of this source may reach high values of the order of 10¹³ to 10¹⁴ A/m2·sr. This source has an acceptable lifetime of more than 1000 hours even when used under relatively high pressure (up to 10⁻³ Pa).

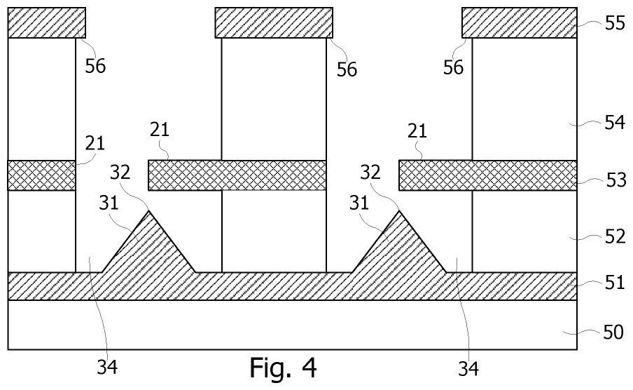

The conductor/vacuum/insulator structure is not necessarily obtained by exploiting the surface roughness of the conductor supporting the insulator. Indeed, this structure may be entirely manufactured using conventional microelectronics techniques. Accordingly, FIG. 4 represents a multilayer structure, according to an embodiment. This structure comprises a substrate 50 on which a conductive layer 51 has been deposited and etched to form nanotips 31 a few nanometers high. An insulating layer 52 was then deposited on the conductive layer 51. The thickness of the conductive layer 51 is slightly greater than the height of the nanotips 31, so that the height between the apexes 32 of the nanotips 31 and the top surface of the insulating layer 52 is a few nanometers. Wells are then formed in the insulating layer 52 to expose the nanotips 31 and the layer 51 around them. The wells are then filled with a sacrificial layer to obtain a flat surface including the top surface of the insulating layer 52. A monocrystalline layer 53 is formed, for example, by chemical vapor deposition (CVD) using a raw gas containing hydrocarbons and hydrogen. The thickness of the layer 53 may lie between 5 and 50 nm, for example 10 nm. The layer 53 is then etched to form a single crystal plate 21 per nanotip 31, with the apex 32 of each nanotip being under one of the plates 21 or flush with an edge thereof.

Anodes are then formed. For this purpose, an electrically insulating layer 54 is deposited on the plates 21 and the sacrificial layer, and then etched to form wells substantially flush with the wells around the nanotips 31. The wells are filled with the sacrificial layer material, and the entire insulating layer 54 and sacrificial layer are covered with a conductive layer 55 which is then etched to form the anodes 56. All of the sacrificial material is then removed from the wells to expose the nanotips, thereby achieving the arrangement shown in FIG. 4.

The nanotips 31 may be arranged in rows and columns to form an array of nanotips usable to form a flat screen operating by cathodoluminescence, to display animated images. The nanotips may be connected to each other line by line and controlled by conductive strips forming anodes 56 arranged in columns, in order to excite a single nanotip located on the line and the column subjected to a voltage.

Of course, other techniques used for manufacturing microelectronic components may be used to manufacture the structure shown in FIG. 4, and some aspects of this structure may vary depending on the intended applications.

It will be apparent to the person skilled in the art that the present invention is susceptible to various embodiments and applications. In particular, the invention is not limited to the materials previously described for the conductive material and the insulating crystal, nor to the shape of the substrate formed at the apex of a tip. Indeed, the surface of the substrate covered by the crystal may be planar, the natural roughness of the substrate being exploited to form the void space under the crystal.

1. A method of manufacturing an electron source, comprising the steps of:
forming a conductive substrate,
arranging a conductor facing the substrate, and
arranging an electrically insulating crystal on the substrate facing the conductor, the substrate delimiting with the crystal a void including at least one peak located at a distance from the crystal, the crystal having, in a plane parallel to the substrate, dimensions of less than 100 nm, and in a direction perpendicular to the plane, a thickness of less than 50 nm.

2. The method according to claim 1, comprising a step of depositing the crystal on the substrate, the substrate having a natural roughness forming the void between the substrate and the crystal.

3. The method according to claim 2, wherein the deposition of the crystal on the substrate is performed by depositing on the substrate a drop containing crystals suspended in deionized water, the drop being produced at an outlet port at a tapered end of a nanopipette by exerting pressure on an inlet port of the nanopipette.

4. The method of claim 3, comprising the steps of:
partially filling the nanopipette with deionized water,
locally heating the nanopipette to vaporize the water, wherein the water in vapor form is condensed near the tapered end of the nanopipette, and
filling the nanopipette with deionized water containing suspended crystals.

5. The method according to claim 1, comprising the steps of machining an end of a conductive wire to form a tip and, at an apex of the tip, forming a plateau forming the conductive substrate.

6. The method of claim 5, wherein an extent of the plateau and an inclination of the tip are adjusted according to a desired divergence of an electron beam produced by the electron source.

7. The method of claim 1, comprising the steps of:
forming a nanotip in the substrate,
depositing an insulating layer on the substrate,
forming a well in the insulating layer to expose the nanotip,
filling the well with a sacrificial layer,
depositing a single crystal layer on the insulating layer and the sacrificial layer,
etching the single crystal layer to form a monocrystalline plate having an edge plumb with an apex of the nanotip, and
removing the sacrificial layer to form the void between the substrate and the monocrystalline plate.

8. An electron source comprising:
a conductive substrate,
a conductor arranged facing the substrate, the electron source emitting an electron beam when the conductor is positively biased with respect to the substrate, and
an electrically insulating crystal arranged on the substrate, facing the conductor, the substrate delimiting with the crystal a void including at least one peak located at a distance from the crystal, the crystal having, in a plane parallel to the substrate, dimensions of less than 100 nm and a thickness of less than 50 nm.

9. The electron source of claim 8, wherein the crystal is placed on the substrate, the substrate having a natural roughness forming the void between the crystal and the substrate, the crystal being supported by peaks on a surface of the substrate.

10. The electron source of claim 8, wherein the substrate is formed by a plateau at an apex of a tip at one end of a wire.

11. The electron source of claim 10, wherein the plateau has a width between 5 and 50 μm.

12. The electron source of claim 8, wherein the substrate has a nanotip located at a distance from the substrate in the void beneath the crystal or in a vicinity of an edge of the crystal, the void being formed by a well formed around and above the nanotip in an electrically insulating layer supporting the crystal.

13. The electron source of claim 8, wherein the substrate is tungsten or carbon, and the crystal is diamond or talcum.

14. The electron source of claim 8, wherein the crystal has a width of 50 nm and a thickness of 10 nm, these dimensions being defined to within ±10%.
